(19) United States
(12) Patent Application Publication
(10) Pub. No.: US 2025/0299946 A1
(43) Pub. Date: Sep. 25, 2025

(54) METHOD FOR FORMING CONFORMAL SILICON OXIDE THIN FILM

(71) Applicant: Applied Materials, Inc., Santa Clara, CA (US)

(72) Inventors: Xinke Wang, Singapore (SG); Bhaskar Jyoti Bhuyan, San Jose, CA (US); Thai Cheng Chua, Cupertino, CA (US); Lakmal C. Kalutarage, San Jose, CA (US); Mark Saly, Santa Clara, CA (US); John Sudijiono, Singapore (SG)

(73) Assignee: Applied Materials, Inc., Santa Clara, CA (US)

(21) Appl. No.: 18/609,206

(22) Filed: Mar. 19, 2024

(51) Int. Cl. H01L 21/02; C23C 16/40; C23C 16/44; C23C 16/455; C23C 16/511; H01J 37/32

(52) U.S. Cl. CPC H01L 21/02274; C23C 16/401; C23C 16/4408; C23C 16/45542; C23C 16/45553; C23C 16/511; H01J 37/32192; H01J 37/32357; H01L 21/02164; H01L 21/02208; H01L 21/0228; H01J 2237/332

(57) ABSTRACT

Methods of depositing high-quality conformal silicon oxide (SiOx) films in the formation of semiconductor devices are described. The methods include exposing a semiconductor substrate to a first precursor, a first purge gas, a second precursor, a second purge gas, and a remote plasma source (RPS) microwave plasma to deposit a conformal silicon oxide (SiOx) film.

### TECHNICAL FIELD

Embodiments of the disclosure relate to methods for depositing a films in the manufacture of semiconductor devices. In particular, embodiments of the disclosure are directed to methods of depositing high-quality conformal silicon oxide (SiOₓ) layers in the formation of high aspect ratio semiconductor devices.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

The advancing complexity of advanced microelectronic devices is placing stringent demands on currently used deposition techniques. Unfortunately, there are a limited number of viable chemical precursors available that have the requisite properties of robust thermal stability, high reactivity, and vapor pressure suitable for film growth to occur. In addition, precursors that often meet these requirements still suffer from poor long-term stability and lead to thin films that contain elevated concentrations of contaminants such as oxygen, nitrogen, and/or halides that are often deleterious to the target film application.

Performance of semiconductor devices having high aspect ratio openings is related to the characteristics of the materials used as well as the thickness and area of the structural layers. As some characteristics are adjusted, however, to accommodate device scaling, challenges arise. With chemical vapor deposition (CVD), plasma enhanced chemical vapor deposition (PECVD), and plasma enhanced atomic layer deposition (PEALD), it is difficult to obtain high-quality (low wet etch rate (WER)) conformal silicon oxide (SiOₓ) films on high aspect ratio structures, especially on reentrant structures such as GAA and 3D DRAM.

Silicon oxide (SiOₓ) films have attractive material and electrical properties for semiconductor devices. These films have been proposed and tested for applications from front-end to back-end parts of semiconductor and microelectronic devices. Most of the current state-of-art approaches for atomic layer deposition of silicon oxide (SiOₓ) films are based on silane precursors which contain halogens. The halogen contamination may affect device performance and hence require additional removal procedures. Also, sometimes, halogen removal requires higher thermal budget. The use of high temperature processes is not desirable for temperature-sensitive substrates (e.g., logic and memory devices).

Accordingly, there is a need in the art for logic or memory devices having high quality silicon oxide (SiOₓ) films. Additionally, there is a need in the art for methods to form high-quality conformal silicon oxide (SiOₓ) films for logic or memory devices.

### SUMMARY

One or more embodiments of the disclosure are directed to a method of depositing a film on a semiconductor device. A method of depositing a film on a semiconductor device comprises: exposing a semiconductor substrate in a semiconductor processing chamber to a first precursor; exposing the semiconductor substrate to a first purge gas; exposing the semiconductor substrate to a second precursor; exposing the semiconductor substrate to a second purge gas; and exposing the semiconductor substrate to a remote plasma source (RPS) microwave plasma to deposit a conformal silicon oxide (SiOx) film on a surface of the semiconductor substrate.

Another embodiment of the disclosure is directed to a method of manufacturing a logic or memory device. In one or more embodiments, a method of manufacturing a logic or memory device comprises: in a deposition cycle, exposing a substrate comprising at least one feature having a top surface, a sidewall surface, and a bottom surface in a semiconductor processing chamber to a first precursor comprising a silicon-containing precursor, a first purge gas, a second precursor comprising an oxidizing agent, a second purge gas, and a remote plasma source (RPS) microwave plasma to conformally deposit a silicon oxide (SiOx) film on one or more of the top surface, the sidewall surface, and the bottom surface of the at least one feature.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method of depositing a film on a substrate according to one or more embodiments;

FIG. 2A illustrates a cross-section view of a substrate according to one or more embodiments;

FIG. 2B illustrates a cross-section view of a substrate according to one or more embodiments; and

FIG. 3 illustrates a cluster tool according to one or more embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the semiconductor device in use or operation in addition to the orientation depicted in the Figures. For example, if the semiconductor device in the Figures is turned over, elements described as “below” or “beneath” other elements would then be oriented “above” the other elements. Thus, the exemplary term “below” may encompass both an orientation of above and below. The semiconductor device may be otherwise oriented (rotated 90 degrees or at other orientations) and the spatially relative descriptors used herein interpreted accordingly.

As used herein, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more layers or features deposited or formed thereon.

A “substrate” as used herein, refers to any substrate or material surface formed on a substrate upon which layer processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate, anneal and/or bake the substrate surface. In addition to layer processing directly on the surface of the substrate itself, in the present disclosure, any of the layer processing steps disclosed may also be performed on an under-layer formed on the substrate as disclosed in more detail below, and the term “substrate surface” is intended to include such under-layer as the context indicates. Thus, for example, where a layer/layer or partial layer/layer has been deposited onto a substrate surface, the exposed surface of the newly deposited layer/layer becomes the substrate surface.

For the avoidance of doubt, no stoichiometric ratios are implied by the identification of materials disclosed herein. For example, a silicon oxide (SiO) material contains silicon and oxygen, a silicon nitride (SiN) material contains silicon and nitrogen, and a silicon oxynitride (SiON) material contains silicon, oxygen, and nitrogen. These elements may or may not be present at a 1:1 ratio, or a 1:1:1 ratio, unless otherwise specified herein.

It will be appreciated that the methods described herein can be implemented on any substrate surface having one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor”, “reactant”, “reactive gas”, and the like are used interchangeably to refer to any gaseous species that can react with the substrate surface.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), neon (Ne), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more of the layers deposited on the substrate or substrate surface are conformal. As used herein, the term “conformal” means that the layer adapts to the contours of a feature or a layer. Conformality of a layer is typically quantified by a ratio of the average thickness of a layer deposited on the sidewalls of a feature to the average thickness of the same deposited layer on the field, or upper surface, of the substrate. As used herein, a layer that is “conformally deposited” refers to a layer where the thickness is about the same throughout. A layer which is conformal varies in thickness by less than or equal to about 5%, 2%, 1% or 0.5%. In one or more embodiments, the deposited film has a conformality greater than 90%, or greater than 91%, or greater than 92%, or greater than 93%, or greater than 94%, or greater than 95%, or greater than 96%, or greater than 97%, or greater than 98%, or greater than 99%.

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated Is and current entering the channel at the drain (D) is designated Ip. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is a n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

Previous methods include forming a silicon oxide (SiOx) film on a substrate surface using atomic layer deposition (ALD) or plasma enhance atomic layer deposition (PEALD). The resulting silicon oxide films are of low quality (having a high wet etch in dilute hydrofluoric acid (DHF), do not possess conformality that is well suited for high aspect ratio (HAR) structures, have high current leakage, and high breakdown field.

Embodiments of the present disclosure advantageously provide plasma enhanced atomic layer deposition (PEALD) methods of depositing high-quality (low wet etch rate (WER)) conformal silicon oxide (SiOx) films, without damaging the surrounding semiconductor structures. The methods of one or more embodiments advantageously employ a RPS microwave as a plasma source for PEALD. In one or more embodiments, the RPS microwave process advantageously eliminates the ion bombardment effect on the silicon oxide (SiOx) film.

In one or more embodiments, the methods described herein advantageously provide silicon oxide (SiOx) films having good conformality on high aspect ratio structures, are high-quality films having a low WER, and possess desirable electrical properties.

One or more embodiments advantageously provide a conformal silicon oxide (SiOx) film as a dielectric material for a GAA structure. One or more embodiments advantageously provide a conformal silicon oxide (SiOx) film as a dielectric material for a 3D-DRAM structure. Some embodiments advantageously provide methods of depositing silicon oxide (SiOx) films directly on a semiconductor substrate surface. In one or more embodiments, the deposited silicon oxide (SiOx) film has a low dielectric constant (k). In some embodiments, the dielectric constant is less than 4.5 (k<4.5), or less than 4.0 (k<4.0).

As used herein, the term “high-quality” means that the deposited silicon oxide (SiOx) film has a wet etch rate of less than 30 Å/min in 100:1 dilute hydrofluoric acid (DHF), or a wet etch rate of less than 5 Å/min in 500:1 dilute hydrofluoric acid (DHF).

As used herein, the term “low current leakage” means that the deposited silicon oxide (SiOx) film has a leakage current less than 1×10⁻⁶ A/cm² at 2 MV/cm. As used herein, the term “high breakdown field” means that the deposited silicon oxide (SiOx) film has a breakdown field greater than 6 MV/cm.

As recognized by one of skill in the art, it is difficult to obtain conformal films having uniform compositions using plasma processes in devices having high aspect ratios, particularly, for example, on the trenches/features of GAA and 3D-DRAM devices. Accordingly, one or more embodiments advantageously provide an RPS microwave as a plasma source for PEALD of conformal silicon oxide (SiOx) films. The PEALD methods of one or more embodiments form conformal films having uniform compositions on high aspect ratio structures.

The embodiments of the disclosure are described by way of the Figures, which illustrate devices (e.g., GAA and 3D DRAM) and processes for forming semiconductor structures in accordance with one or more embodiments of the disclosure. The processes shown are merely illustrative possible uses for the disclosed processes, and the skilled artisan will recognize that the disclosed processes are not limited to the illustrated applications.

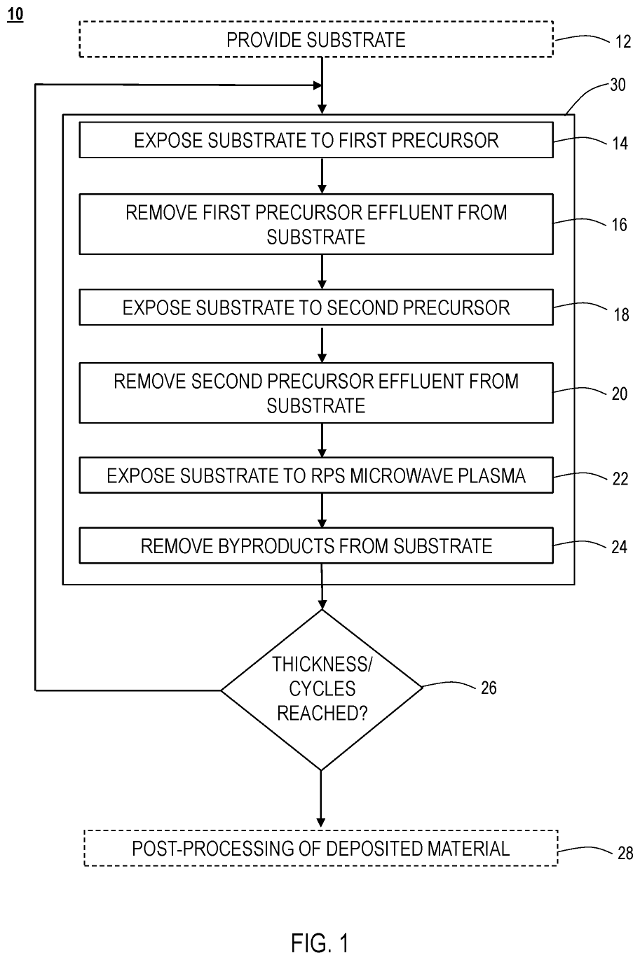

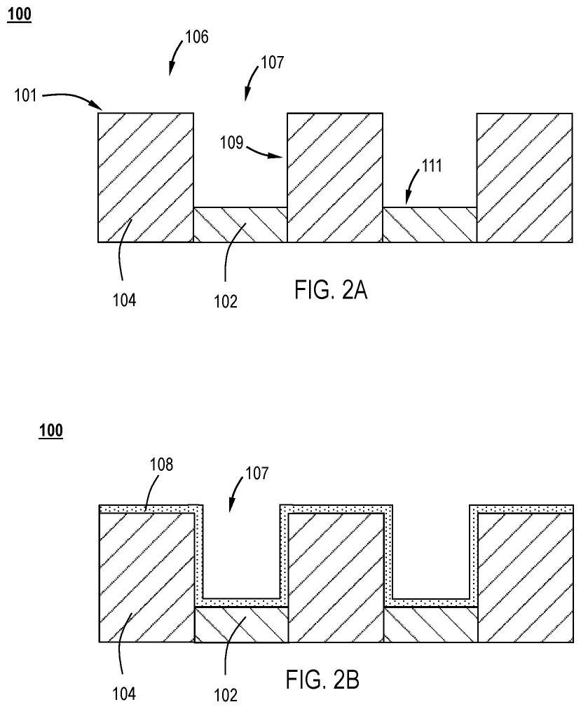

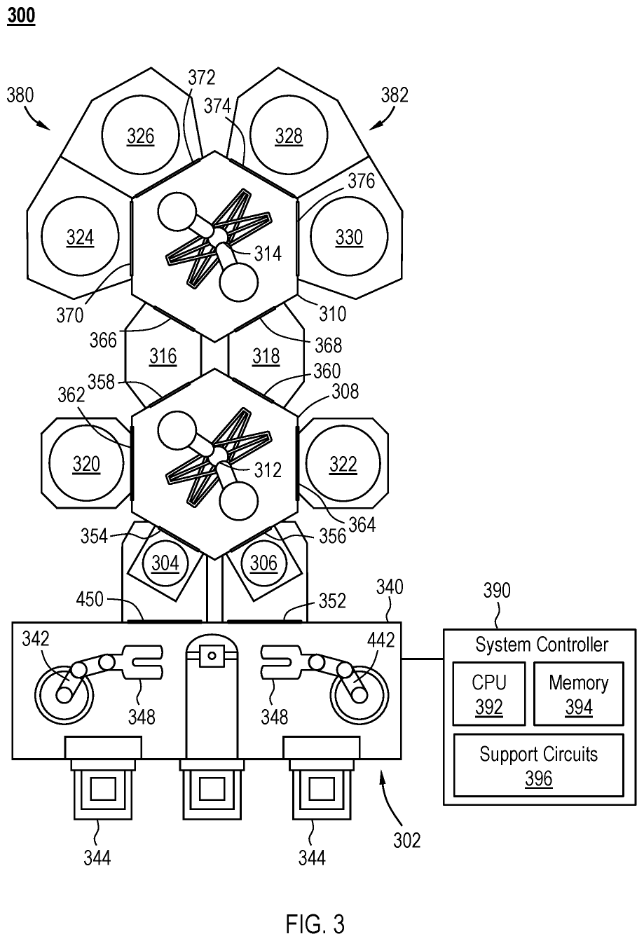

FIG. 1 illustrates a process flow diagram of a method 10 of depositing a film according to one or more embodiments. FIGS. 2A-2B illustrate cross-sectional views of a semiconductor substrate being processed according to the method of one or more embodiments. FIG. 3 illustrates a cluster tool 300 in which any of the semiconductor devices described herein, e.g., semiconductor device 100 can be manufactured and any of the methods described herein e.g., method 10, can be performed.

Referring to FIG. 1 and FIGS. 2A-2B, in one or more embodiments, at operation 12, a substrate is provided. As used in this specification and the appended claims, the term “provided” means that the substrate is made available for processing (e.g., positioned in a processing chamber).

Referring to FIG. 2A, in one or more embodiments, a substrate includes a first surface 102 and a second surface 104. In one or more embodiments, the first surface 102 comprises a first material, and the second surface 104 comprises a second material. In some embodiments, the first material and the second material are the same. In other embodiments, the first material and the second material are different.

In one or more embodiments, the first surface 102 comprises a metal material. In one or more embodiments, the second surface 104 comprises a dielectric surface. In other embodiments, the second surface 104 comprises one or more of a dielectric surface, a semiconductor surface, a non-metal surface, or a metal surface where the metal is different from the metal of the first surface 102.

In one or more embodiments, the substrate on which the silicon oxide (SiOx) layer 107 is formed may include a material in which one or more feature(s) 107 may be formed. The substrate feature(s) 107 may be characterized by any shape or configuration according to the present technology. In some embodiments, the feature(s) 107 may be or include a trench structure, a via structure, or aperture formed within the substrate. Although the substrate feature(s) 107 may be characterized by any shape or size, in some embodiments the substrate feature(s) 107 may be characterized by higher aspect ratios, or a ratio of a depth of the feature to a width across the feature. For example, in some embodiments substrate feature(s) 107 may be characterized by aspect ratios greater than or equal to 5:1, and may be characterized by aspect ratios greater than or equal to 10:1, greater than or equal to 15:1, greater than or equal to 20:1, greater than or equal to 25:1, greater than or equal to 30:1, greater than or equal to 40:1, greater than or equal to 50:1, or greater. Additionally, the feature(s) 107 may be characterized by narrow widths or diameters across the feature including between two sidewalls, such as a dimension less than or equal to 20 nm, and may be characterized by a width across the feature of less than or equal to 15 nm, less than or equal to 12 nm, less than or equal to 10 nm, less than or equal to 9 nm, less than or equal to 8 nm, less than or equal to 7 nm, less than or equal to 6 nm, less than or equal to 5 nm, or less. In one or more embodiments, the feature(s) 107 has a top surface 106, at least one sidewall surface 109, and a bottom surface 111.

A “metal,” as used herein, refers to metal, metallic, metal alloy, metal oxide, metal nitride, or combination thereof. A “metal surface”, as used herein, refers to any portion of a substrate or portion of a material surface formed with the metal. The metal surface may be exposed to a pretreatment process to polish, coat, dope, etch, reduce, oxidize, hydroxylate, anneal, UV cure, e-beam cure and/or bake the substrate. In addition to the pretreatment directly on the metal surface itself, in the present disclosure, any of the metal surface treatment disclosed may also be performed on an underlayer metal surface as disclosed in more detail below, and the term “metal surface” is intended to include such underlayer as the context indicates. Thus, for example, where a film/layer or partial film/layer has been deposited onto the metal surface, the exposed surface of the newly deposited film/layer becomes the metal surface.

In one or more embodiments, the first surface 102 comprises a metal, a metal alloy, a metal oxide, a metal nitride, or a combination thereof. In one or more embodiments, the second surface 104 comprises a metal, a metal alloy, a metal oxide, a metal nitride, or a combination thereof. Non-limiting examples of metal include copper (Cu), cobalt (Co), nickel (Ni), tungsten (W), ruthenium (Ru), chromium (Cr), iron (Fe), platinum (Pt), gold (Au), silver (Ag), molybdenum (Mo), gallium (Ga), indium (In), tungsten (W), titanium (Ti), tantalum (Ta), aluminum (Al), nickel (Ni), oxides thereof, or combinations thereof. In one or more specific embodiments, the first surface 102 comprises one or more of copper (Cu), cobalt (Co), ruthenium (Ru), tungsten (W), molybdenum (Mo), titanium nitride (TiN), tantalum nitride (TaN), titanium (Ti), tantalum (Ta), aluminum (AI), nickel (Ni), or oxides thereof.

In one or more embodiments, the first surface 102 comprises a dielectric material. In one or more embodiments, the second surface 104 comprises a dielectric material. A “dielectric surface,” as used herein, refers to any portion of a substrate or portion of a material surface formed with the dielectric material. Non-limiting examples of dielectric material include silicon oxide (SiOₓ), silicon nitride (SiₓN_{y}), silicon (Si), silicon oxynitride (SiON), carbides, oxycarbides, nitrides, oxynitrides, oxycarbonitrides, polymers, phosphosilicate glass, fluorosilicate (SiOF) glass, organosilicate glass (SiOCH), aluminum oxide (AlOₓ), hafnium oxide (HfOₓ), zirconium oxide (ZrO₂), titanium oxide (TiOₓ), titanium nitride (TiN), tantalum oxide (TaₓO₅), yttrium oxide (Y₂O₃), lanthanum oxide (La₂O₃), aluminum nitride (AlN), magnesium oxide (MgO), calcium fluoride (CaF₂), lithium fluoride (LiF), strontium oxide (SrO), silicon carbide (SiC), barium oxide (BaO), hafnium silicate (HfSiO₄), lanthanum aluminate (LaAlO₃), niobium pentoxide (Nb₂O₅), barium titanate (BaTiO₃), strontium titanate (SrTiO₃), bismuth titanate (Bi₄Ti₃O₁₂), lead zirconium titanate (Pb(Zr, Ti)O₃), calcium copper titanate (CaCu₃Ti₄O₁₂), lithium niobate (LiNbO₃), barium titanate (BaTiO₃), and potassium niobate (KNbO₃). In one or more embodiments, the second surface ₁₀₄ comprises one or more of silicon oxide (SiOₓ), silicon oxycarbide (SiOC), silicon oxycarbonitride (SiOCN), silicon nitride (SiN), silicon oxynitride (SiON), silicon (Si), germanium (Ge), silicon germanium (SiGe), silicon carbide (SiC), indium gallium zinc oxide (InGaZnO), aluminum oxide (AlOₓ), aluminum nitride (AlN), and hafnium oxide (HfOₓ).

Referring to FIG. 1, one or more embodiments of the disclosure are directed to method 10 of depositing a film. The method illustrated in FIG. 1 is representative of a plasma enhanced atomic layer deposition (PEALD) process in which the substrate or substrate surface is exposed sequentially to the reactive gases in a manner that prevents or minimizes gas phase reactions of the reactive gases. In some embodiments, the methods may comprise a plasma enhance chemical vapor deposition (PECVD) process in which the reactive gases are mixed in the processing chamber to allow gas phase reactions of the reactive gases and deposition of the thin film.

Referring to FIG. 1 and FIGS. 2B, at deposition 30 or deposition cycle 30, a process is performed to deposit a conformal silicon oxide (SiOx) film 108 on the substrate (or substrate surface. The deposition process can include one or more operations to form a film on the substrate. At operation 14, the substrate (or substrate surface) is exposed to a first precursor, e.g., a silicon-containing precursor, to deposit a film on the substrate (or substrate surface). The silicon-containing precursor can be any suitable compound that can react with (i.e., adsorb or chemisorb onto) the substrate surface to leave a silicon-containing species on the substrate surface.

In one or more embodiments, the first precursor may comprise any suitable silicon-containing precursor known to the skilled artisan. In one or more embodiments, the first precursor comprises a disilacyclobutane precursor or a trisilacyclohexane precursor. In one or more embodiments, the first precursor comprises one or more of a disilacyclobutane, a precursor having a formula R³R²R¹—Si—CₓH₂ₓ—Si—R¹R²R³, wherein R¹, R², R³ are independently selected from hydrogen (H), dimethylamino, diethylamino, alkyl, alkoxy, vinyl, silane, amine, or halide, x is an integer in a range of from 1 to 10, or in a range of from 2 to 10, or a trisilacyclohexane precursor.

In some embodiments, the first precursor is a disilacyclobutane having the general formula (I):

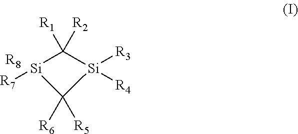

wherein R¹, R², R³, R⁴, R⁵, R⁶, R⁷, and R⁸ are independently selected from hydrogen (H), alkyl, alkoxy, vinyl, silane, amine, dimethylamino, or halide. In specific embodiments, R¹, R², R⁵, and R⁶ are hydrogen, and R³, R⁴, R⁷, and R⁸ are independently selected from hydrogen (H), alkyl, alkoxy, vinyl, silane, amine, dimethylamino, or halide.

In one or more embodiments, the first precursor comprises one or more of bis(tris(dimethylamido)silyl)methane, bis(trichlorosilyl)methane, 1,1,3,3-tetrakis(dimethylamino)-1,3-disilacyclobutane.

In one or more embodiments, the first precursor is a trisilacyclohexane precursor having the general formula (II)

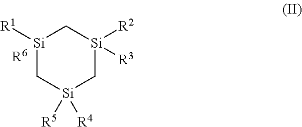

wherein R¹, R², R³, R⁴, R⁵, and R⁶ are independently selected from hydrogen (H), alkyl, alkoxy, vinyl, silane, amine, dimethylamino, or halide.

Unless otherwise indicated, the term “lower alkyl,” “alkyl,” or “alk” as used herein alone or as part of another group includes both straight and branched chain hydrocarbons, containing 1 to 24 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents.

As used herein, the term “alkoxy” includes any of the above alkyl groups linked to an oxygen atom.

As used herein, the terms “vinyl” or “vinyl-containing” refer to groups containing the vinyl group (—CH═CH₂).

As used herein, the term “amine” relates to any organic compound containing at least one basic nitrogen atom, e.g., NR′₂, wherein R′ is independently selected from hydrogen (H) or alkyl.

As used herein, the term “silane” refers to a compound SiR′₃, wherein R′ is independently selected from hydrogen (H) or alkyl.

As used herein, the term “halide” refers to a binary phase, of which one part is a halogen atom and the other part is an element or radical that is less electronegative than the halogen, to make a fluoride, chloride, bromide, iodide, or astatide compound. A halide ion is a halogen atom bearing a negative charge. As known to those of skill in the art, a halide anion includes fluoride (F—), chloride (Cl—), bromide (Br—), iodide (I—), and astatide (At—).

The deposition 30 can occur at any suitable temperature, pressure, and exposure duration known to the skilled artisan. In some embodiments, the substrate (or substrate surface) is exposed to a first precursor and a second precursor at a pressure in a range of from 0.1 Torr to 100 Torr, or in a range of from 1 Torr to 50 Torr, and at a temperature in a range of from 200° C. to 550° C.

As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the silicon oxide (SiOx) film, for example, by polishing, etching, reduction, oxidation, halogenation, hydroxylation, annealing, baking, or the like. In some embodiments, the substrate surface is part of a gate-all-around (GAA) device or a 3D-DRAM device.

At operation 16, the processing chamber or substrate surface is purged to remove unreacted first precursor, reaction products, and by-products. As used in this manner, the term “processing chamber” also includes portions of a processing chamber adjacent to the substrate surface without encompassing the complete interior volume of the processing chamber. For example, in a sector of a spatially separated processing chamber, the portion of the processing chamber adjacent the substrate surface is purged of the first precursor by any suitable technique including, but not limited to, moving the substrate through a gas curtain to a portion or sector of the processing chamber that contains none or substantially none of the first precursor. In one or more embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from, but not limited to, one or more of nitrogen (N₂), helium (He), neon (Ne), and argon (Ar). Purging the processing chamber, portion of the processing chamber, area adjacent the substrate surface, etc., removes unreacted reactants, reaction products, and by-products from the area adjacent the substrate surface.

At operation 18, the substrate (or substrate surface) is exposed to a second precursor to form a conformal silicon oxide (SiOx) film 108 on the substrate. The second precursor may comprise any suitable precursor known to the skilled artisan. In one or more embodiments, the second precursor comprises an oxidizing agent. The second precursor can react with the silicon-containing species on the substrate surface to form the conformal silicon oxide (SiOx) film 108.

In one or more embodiments, the second precursor comprises one or more of a carboxylic acid, alcohol, e.g., methanol, ethanol, propanol, iso-propanol, and the like, acetic acid, ethylene glycol, oxygen (O₂), ozone (O₃), hydrogen peroxide (H₂O₂), and water (H₂O).

Exposure to the second precursor at operation 18 can occur at any suitable temperature, pressure, and exposure duration known to the skilled artisan. In some embodiments, the substrate (or substrate surface) is exposed to the second precursor at a pressure in a range of from 0.1 Torr to 100 Torr, or in a range of from 1 Torr to 50 Torr, and at a temperature in a range of from 200° C. to 550° C.

As recognized by one of skill in the art, the order that the substrate or substrate surface is exposed to the first precursor and the second precursor may be reversed. For example, in some embodiments, the substrate or substrate surface may be exposed to the second precursor at operation 14, followed by exposure to the first precursor at operation 18.

At operation 20, the processing chamber is purged after exposure to the second precursor. Purging the processing chamber in operation 20 can be the same process or different process than the purge in operation 16. Purging the processing chamber, portion of the processing chamber, area adjacent the substrate surface, etc., removes unreacted silane reactant, reaction products, and by-products from the area adjacent the substrate surface.

Referring to FIG. 1, at operation 22, the substrate is exposed to a remote plasma source (RPS) microwave plasma. In one or more embodiments, the method 10 at operation 22 uses a remote plasma source outside the plasma processing chamber and delivers the remotely generated plasma to the plasma processing chamber or strikes the plasma in the plasma processing chamber to introduce the plasma into the process area of the chamber. In one or more embodiments, the RPS microwave plasma operates at frequencies at greater than 300 MHz and less than 30 GHz, for example, 2.45 GHz, and has very high charge and plasma densities compared to capacitive plasma sources. The plasma densities in some embodiments range from 10¹²/cm³ to 10¹³/cm³, and ion energies in some embodiments are less than 10 eV.

In one or more embodiments, the RPS microwave plasma comprises hydrogen (H₂) or hydrogen (H₂) mixed with an inert gas. The inert gas may comprise any suitable inert gas including, but not limited to argon (Ar), helium (He), neon (Ne), and nitrogen (N₂). In one or more embodiments, the remote microwave plasma source generates a microwave plasma with a high frequency. The microwave plasma may be with or without an ion blocker. In one or more embodiments, the plasma setting is to produce a plasma having high hydrogen radical (H*) density with minimal or no ion bombardment.

Still referring to FIG. 1, at operation 24, the processing chamber is purged after exposure to the RPS microwave plasma. Purging the processing chamber in operation 24 can be the same process or different process than the purge in operations 16 and 20. Purging the processing chamber, portion of the processing chamber, area adjacent the substrate surface, etc., removes unreacted silane reactant, reaction products, and by-products from the area adjacent the substrate surface.

With reference to FIG. 1, at decision 26, the thickness of the deposited silicon oxide (SiOx) film 108, or number of cycles of first precursor and the second precursor is considered. If the deposited film has reached a predetermined thickness or a predetermined number of process cycles have been performed, the method 10 moves to the post-processing operation 28. If the thickness of the deposited silicon oxide (SiOx) film 108 or the number of process cycles has not reached the predetermined threshold, the method 10 returns to deposition 30 to expose the substrate surface to the first precursor again in operation 14 and continuing.

In one or more embodiments, the silicon oxide (SiOx) film 108 formed by method 10 may have any suitable thickness. The skilled artisan will recognize that the particular thickness of the silicon oxide (SiOx) film 108 may depend on the particular application. In some embodiments, the deposited silicon oxide (SiOx) film 108 has a thickness in a range of from 1 Å to 200 Å, including in a range of from 5 Å to 100 Å, and a range of from 10 Å to 60 Å.

In one or more embodiments, the silicon oxide (SiOx) film 108 formed by method 10 is resistant to etching by dilute hydrofluoric acid (DHF). Accordingly, in one or more embodiments, the wet etch rate (WER) of the silicon oxide (SiOx) film 108 is low. In some embodiments, the WER in diluted hydrofluoric acid (DHF) solution is less than 30 Å/min in 100:1 DHF. In other embodiments, the WER of the silicon oxide (SiOx) film 108 after deposition is less than 5 Å/min in 500:1 DHF.

In one or more embodiments, the silicon oxide (SiOx) film that is formed according to the method 10 has a dielectric constant that is less than 4.5, including less than 4, and less than 3.5.

In one or more embodiments, the silicon oxide (SiOx) film formed by method 10 has a low current leakage, having a current leakage less than 1×10⁻⁶ A/cm² at 2 MV/cm. In one or more embodiments, the silicon oxide (SiOx) film has a breakdown field of greater than 6 MV/cm.

Referring to FIG. 1, the optional post-processing operation 28 can be, for example, a process to modify film properties (e.g., annealing) or a further film deposition process (e.g., additional ALD or CVD processes) to grow additional films. In one or more embodiments, the optional post-processing operation 28 can be a process that modifies a property of the deposited film. In one or more embodiments, the optional post-processing operation 28 comprises one or more of hydrogen (H₂), methane (CH₄), or ammonia (NH₃) plasma treatment. The hydrogen (H₂), methane (CH₄), or ammonia (NH₃) plasma may be mixed with one or more inert gas, such as, but not limited to, argon (Ar), helium (He), nitrogen (N₂), and neon (Ne). The plasma may be one or more of an inductively coupled plasma (ICP), remote plasma source (RPS), microwave, RPS microwave, or capacitively coupled plasma (CCP).

Referring to FIG. 1, the method 10 or deposition 30 can be repeated one or more times to obtain a film having the desired thickness. In one or more embodiments, the deposition 30 is repeated n number of times where n is an integer in a range of from 1 to 1000, including in a range of from 1 to 500, or in a range of from 1 to 350, or in a range of from 1 to 100, or in a range of from 1 to 50, or in a range of from 1 to 10.

According to one or more embodiments, the semiconductor processing chamber in which the method, e.g., method 10, is performed can be maintained at processing conditions, and the processing conditions may be modified based on the particular application. In specific embodiments, as will be appreciated by the skilled artisan, the processing conditions may be modified based upon the type of semiconductor device being manufactured, e.g., a logic device or a memory device.

The semiconductor processing chamber in which the method, e.g., method 10, is performed can be maintained at any suitable temperature. In some embodiments, the semiconductor processing chamber is maintained at a temperature in a range of from >200° C. to 600° C.

FIG. 3 illustrates a schematic top-view diagram of an example of a multi-chamber processing system 300 according to embodiments of the present disclosure. The processing system 300 generally includes a factory interface 302, load lock chambers 304, 306, transfer chambers 308, 310 with respective transfer robots 312, 314, holding chambers 316, 318, and processing chambers 320, 322, 324, 326, 328, 330. As detailed herein, wafers in the processing system 300 can be processed in and transferred between the various chambers without exposing the wafers to an ambient environment exterior to the processing system 300 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 300. Accordingly, the processing system 300 may provide an integrated solution for some processing of wafers.

In the illustrated example of FIG. 3, the factory interface 302 includes a docking station 340 and factory interface robots 342 to facilitate transfer of wafers. The docking station 340 is configured to accept one or more front opening unified pods (FOUPs) 344. In some examples, each factory interface robot 342 generally comprises a blade 348 disposed on one end of the respective factory interface robot 342 configured to transfer the wafers from the factory interface 302 to the load lock chambers 304, 306.

The load lock chambers 304, 306 have respective ports 350, 352 coupled to the factory interface 302 and respective ports 354, 356 coupled to the transfer chamber 308. The transfer chamber 308 further has respective ports 358, 360 coupled to the holding chambers 316, 318 and respective ports 362, 364 coupled to processing chambers 320, 322. Similarly, the transfer chamber 310 has respective ports 366, 368 coupled to the holding chambers 316, 318 and respective ports 370, 372, 374, 376 coupled to processing chambers 324, 326, 328, 330. The ports 354, 356, 358, 360, 362, 364, 366, 368, 370, 372, 374, 376 can be, for example, slit valve openings with slit valves for passing wafers therethrough by the transfer robots 312, 314 and for providing a seal between respective chambers to prevent a gas from passing between the respective chambers. Generally, any port is open for transferring a wafer therethrough. Otherwise, the port is closed.

The load lock chambers 304, 306, transfer chambers 308, 310, holding chambers 316, 318, and processing chambers 320, 322, 324, 326, 328, 330 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 342 transfers a wafer from a FOUP 344 through a port 350 or 352 to a load lock chamber 304 or 306. The gas and pressure control system then pumps down the load lock chamber 304 or 306. The gas and pressure control system further maintains the transfer chambers 308, 310 and holding chambers 316, 318 with an interior low pressure or vacuum environment (which may include an inert gas). Hence, the pumping down of the load lock chamber 304 or 306 facilitates passing the wafer between, for example, the atmospheric environment of the factory interface 302 and the low pressure or vacuum environment of the transfer chamber 308.

With the wafer in the load lock chamber 304 or 306 that has been pumped down, the transfer robot 312 transfers the wafer from the load lock chamber 304 or 306 into the transfer chamber 308 through the port 354 or 356. The transfer robot 312 is then capable of transferring the wafer to and/or between any of the processing chambers 320, 322 through the respective ports 362, 364 for processing and the holding chambers 316, 318 through the respective ports 358, 360 for holding to await further transfer. Similarly, the transfer robot 314 is capable of accessing the wafer in the holding chamber 316 or 318 through the port 366 or 368 and is capable of transferring the wafer to and/or between any of the processing chambers 324, 326, 328, 330 through the respective ports 370, 372, 374, 376 for processing and the holding chambers 316, 318 through the respective ports 366, 368 for holding to await further transfer. The transfer and holding of the wafer within and among the various chambers can be in the low pressure or vacuum environment provided by the gas and pressure control system.

The processing chambers 320, 322, 324, 326, 328, 330 can be any appropriate chamber for processing a wafer. In some embodiments, the processing chamber 320 can be capable of performing an annealing process, the processing chamber 322 can be capable of performing a cleaning process, and the processing chambers 324, 326, 328, 330 can be capable of performing epitaxial growth processes. In some examples, the processing chamber 322 can be capable of performing a cleaning process, the processing chamber 320 can be capable of performing an etch process, and the processing chambers 324, 326, 328, 330 can be capable of performing respective epitaxial growth processes. The processing chamber 322 may be a preclean chamber. The processing chamber 320 may be an etch chamber.

A system controller 390 is coupled to the processing system 300 for controlling the processing system 300 or components thereof. For example, the system controller 390 may control the operation of the processing system 300 using a direct control of the chambers 304, 306, 308, 316, 318, 310, 320, 322, 324, 326, 328, 330 of the processing system 300 or by controlling controllers associated with the chambers 304, 306, 308, 316, 318, 310, 320, 322, 324, 326, 328, 330. In operation, the system controller 390 enables data collection and feedback from the respective chambers to coordinate performance of the processing system 300.

The system controller 390 generally includes a central processing unit (CPU) 392, memory 394, and support circuits 396. The CPU 392 may be one of any form of a general-purpose processor that can be used in an industrial setting. The memory 394, or non-transitory computer-readable medium, is accessible by the CPU 392 and may be one or more of memory such as random-access memory (RAM), read only memory (ROM), floppy disk, hard disk, or any other form of digital storage, local or remote. The support circuits 396 are coupled to the CPU 392 and may comprise cache, clock circuits, input/output subsystems, power supplies, and the like. The various methods disclosed herein may generally be implemented under the control of the CPU 392 by the CPU 392 executing computer instruction code stored in the memory 394 (or in memory of a particular process chamber) as, for example, a software routine. When the computer instruction code is executed by the CPU 392, the CPU 392 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 308, 310 and the holding chambers 316, 318. In other examples, more or fewer transfer chambers (e.g., one transfer chamber) and/or more or fewer holding chambers (e.g., no holding chambers) may be implemented as a transfer apparatus in a processing system.

Processes may generally be stored in the memory of the system controller 390 as a software routine that, when executed by the processor, causes the process chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes a processing chamber to perform the operations of any of the methods (e.g., method 10) described herein. In one or more embodiments, the controller causes a processing chamber to perform the operations of method 10.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of depositing a film on a semiconductor device, the method comprising:
exposing a semiconductor substrate in a semiconductor processing chamber to a first precursor;
exposing the semiconductor substrate to a first purge gas;
exposing the semiconductor substrate to a second precursor;
exposing the semiconductor substrate to a second purge gas; and
exposing the semiconductor substrate to a remote plasma source (RPS) microwave plasma to deposit a conformal silicon oxide (SiOx) film on a surface of the semiconductor substrate.

2. The method of claim 1, wherein the remote plasma source (RPS) microwave plasma comprises hydrogen (H₂) or hydrogen (H₂) mixed with an inert gas.

3. The method of claim 1, wherein the first precursor is a silicon-containing precursor.

4. The method of claim 2, wherein the first precursor comprises a one or more of a disilacyclobutane, a trisilacyclohexane, or a precursor having a formula R³R²R¹—Si—CₓH₂ₓ—Si—R¹R²R³, wherein R¹, R², R³ are independently selected from hydrogen (H), dimethylamino, diethylamino, alkyl, alkoxy, vinyl, silane, amine, or halide, x is an integer in a range of from 1 to 10.

5. The method of claim 4, wherein the disilacyclobutane has a general formula (I): 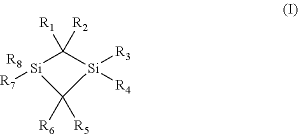
wherein R¹, R², R³, R⁴, R⁵, R⁶, R⁷, and R⁸ are independently selected from hydrogen (H), alkyl, alkoxy, vinyl, silane, amine, dimethylamino, or halide.

6. The method of claim 4, wherein the trisilacyclohexane has a general formula (II): 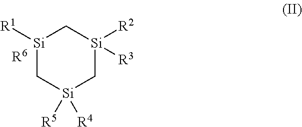
wherein R¹, R², R³, R⁴, R⁵, and R⁶ are independently selected from hydrogen (H), alkyl, alkoxy, vinyl, silane, amine, dimethylamino, or halide.

7. The method of claim 5, wherein the first precursor is selected from the group consisting of bis(tris(dimethylamido)silyl)methane, bis(trichlorosilyl)methane, and 1,1,3,3-tetrakis(dimethylamino)-1,3-disilacyclobutane.

8. The method of claim 1, wherein the second precursor comprises one or more of a carboxylic acid, alcohol, acetic acid, ethylene glycol, oxygen (O₂), ozone (O₃), hydrogen peroxide (H₂O₂), and water (H₂O).

9. The method of claim 1, wherein the conformal silicon oxide (SiOx) film has a dielectric constant less than 4.5.

10. The method of claim 1, wherein the method is repeated n number of times, wherein n is an integer in a range of from 1 to 1000.

11. The method of claim 1, wherein the method is performed at a temperature in a range of from 200° C. to 550° C.

12. The method of claim 1, wherein the first purge gas and the second purge gas are independently selected from argon (Ar), helium (He), neon (Ne), and nitrogen (N₂).

13. A method of manufacturing a logic or memory device, the method comprising:
in a deposition cycle, exposing a substrate comprising at least one feature having a top surface, a sidewall surface, and a bottom surface in a semiconductor processing chamber to a first precursor comprising a silicon-containing precursor, a first purge gas, a second precursor comprising an oxidizing agent, a second purge gas, and a remote plasma source (RPS) microwave plasma to conformally deposit a silicon oxide (SiOx) film on one or more of the top surface, the sidewall surface, and the bottom surface of the at least one feature.

14. The method of claim 13, wherein the remote plasma source (RPS) microwave plasma comprises hydrogen (H₂) or hydrogen (H₂) mixed with an inert gas comprising one or more of argon (Ar), helium (He), neon (Ne), and nitrogen (N₂).

15. The method of claim 13, wherein the first precursor comprises a one or more of a disilacyclobutane, trisilacyclohexane, or a precursor having a formula R³R²R¹—Si—CₓH₂ₓ—Si—R¹R²R³, wherein R¹, R², R³ are independently selected from hydrogen (H), dimethylamino, diethylamino, alkyl, alkoxy, vinyl, silane, amine, or halide, x is an integer in a range of from 2 to 10.

16. The method of claim 15, wherein the disilacyclobutane has a general formula (I) and the trisilacyclohexane has a general formula (II): 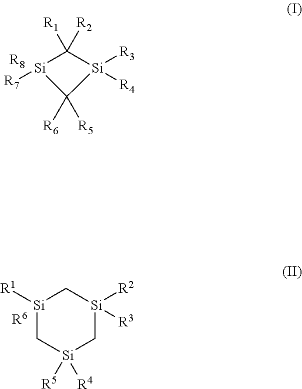
wherein R¹, R², R³, R⁴, R⁵, R⁶, R⁷, and R⁸ are independently selected from hydrogen (H), alkyl, alkoxy, vinyl, silane, amine, dimethylamino, or halide.

17. The method of claim 13, wherein the conformal silicon oxide (SiOx) film has a dielectric constant less than 4.5.

18. The method of claim 13, wherein the deposition cycle is repeated n number of times, wherein n is an integer in a range of from 1 to 1000.

19. The method of claim 13, wherein the method is performed at a temperature in a range of from 200° C. to 550° C.

20. The method of claim 13, wherein the first purge gas and the second purge gas are independently selected from argon (Ar), helium (He), neon (Ne), and nitrogen (N₂).
